(19) United States
(12) Patent Application Publication
(10) Pub. No.: US 2024/0168637 A1
(43) Pub. Date: May 23, 2024

(54) PRIORITIZING REFRESH OPERATIONS OF A MEMORY SYSTEM

(71) Applicant: Micron Technology, Inc., Boise, ID (US)

(72) Inventors: Nicola Colella, Capodrise (IT); Rakeshkumar Dayabhai Vaghasiya, Hyderabad (IN); Dhruv Chauhan, Hyderabad (IN); Anilkumar Rameshbhai Sindhi, Hyderabad (IN)

(21) Appl. No.: 18/506,873

(22) Filed: Nov. 10, 2023

Related U.S. Application Data
(60) Provisional application No. 63/384,719, filed on Nov. 22, 2022.

(51) Int. Cl. G06F 3/06

(52) U.S. Cl. CPC G06F 3/0611; G06F 3/0659; G06F 3/0679

(57) ABSTRACT

Methods, systems, and devices for prioritizing refresh operations of a memory system are described. In some instances, a memory system may refresh one or more production state awareness (PSA) blocks at power-on. In some cases, the PSA blocks that are refreshed may have relatively high bit error rates (BERs). For example, PSA blocks with relatively high BERs that are not refreshed may increase the risk of system failure or malfunction. Other PSA blocks may not be refreshed at power-on, and may instead be refreshed at a later time based on one or more criteria in order to prioritize refreshing the PSA blocks having relatively high BERs.

### CROSS REFERENCE

The present application for patent claims the benefit of U.S. Provisional Patent Application No. 63/384,719 by COLELLA et al., entitled “PRIORITIZING REFRESH OPERATIONS OF A MEMORY SYSTEM,” filed Nov. 22, 2022, assigned to the assignee hereof, and expressly incorporated by reference herein.

### FIELD OF TECHNOLOGY

The following relates to one or more systems for memory, including prioritizing refresh operations of a memory system.

### BACKGROUND

Memory devices are widely used to store information in various electronic devices such as computers, user devices, wireless communication devices, cameras, digital displays, and the like. Information is stored by programming memory cells within a memory device to various states. For example, binary memory cells may be programmed to one of two supported states, often corresponding to a logic 1 or a logic 0. In some examples, a single memory cell may support more than two possible states, any one of which may be stored by the memory cell. To access information stored by a memory device, a component may read (e.g., sense, detect, retrieve, identify, determine, evaluate) the state of one or more memory cells within the memory device. To store information, a component may write (e.g., program, set, assign) one or more memory cells within the memory device to corresponding states.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), 3-dimensional cross-point memory (3D cross point), not-or (NOR) and not-and (NAND) memory devices, and others. Memory devices may be described in terms of volatile configurations or non-volatile configurations. Volatile memory cells (e.g., DRAM) may lose their programmed states over time unless they are periodically refreshed by an external power source. Non-volatile memory cells (e.g., NAND) may maintain their programmed states for extended periods of time even in the absence of an external power source.

### BRIEF DESCRIPTION OF THE DRAWINGS

FIG. 1 illustrates an example of a system that supports prioritizing refresh operations of a memory system in accordance with examples as disclosed herein.

FIG. 2 illustrates an example of a system that supports prioritizing refresh operations of a memory system in accordance with examples as disclosed herein.

FIG. 3 illustrates an example of a system that supports prioritizing refresh operations of a memory system in accordance with examples as disclosed herein.

FIG. 4 illustrates an example of a process flow diagram that supports prioritizing refresh operations of a memory system in accordance with examples as disclosed herein.

FIG. 5 shows a block diagram of a memory system that supports prioritizing refresh operations of a memory system in accordance with examples as disclosed herein.

FIG. 6 shows a flowchart illustrating a method or methods that support prioritizing refresh operations of a memory system in accordance with examples as disclosed herein.

### DETAILED DESCRIPTION

In some cases, data may be written to one or more blocks of a memory device prior to it being packaged in a memory system (e.g., before a reflow process). Blocks of memory cells having been written (e.g., pre-loaded) with data may be referred to as production state awareness (PSA) blocks. During manufacturing, the memory device may be attached (e.g., soldered) to a circuit board or other component. This process may expose the memory device to relatively high thermal stresses (e.g., temperatures), which may negatively affect the PSA blocks (e.g., may affect the data stored in the PSA blocks). To mitigate errors caused by the attaching process, memory systems may refresh the PSA blocks at power-on. However, as greater quantities of data are preloaded to memory devices, the duration used to refresh the PSA blocks at power-on may increase, thus increasing the overall latency of the memory system. Accordingly, a memory system configured to prioritize refreshing certain PSA blocks at power-on, and refresh other PSA blocks at a later time, may be desirable.

A memory system configured to prioritize refreshing certain blocks at power-on, and other blocks at a later time (e.g., after a subsequent power-on), is described herein. For example, the present approach improves system performance by refreshing PSA blocks having a relatively high bit error rate (BER) at power-on (e.g., after a reflow process), and refreshing other PSA blocks at a later time. PSA blocks with relatively high BERs, when left uncorrected (e.g., not refreshed), may increase the risk of system failure or malfunction. Other PSA blocks with relatively lower BERs may not be refreshed right away, and may instead be refreshed at a later time based on one or more criteria. By prioritizing refresh operations on certain PSA blocks, the system may ensure that PSA blocks that are may increase the risk of system failure or malfunction are refreshed, and may also reduce system latency at power-up.

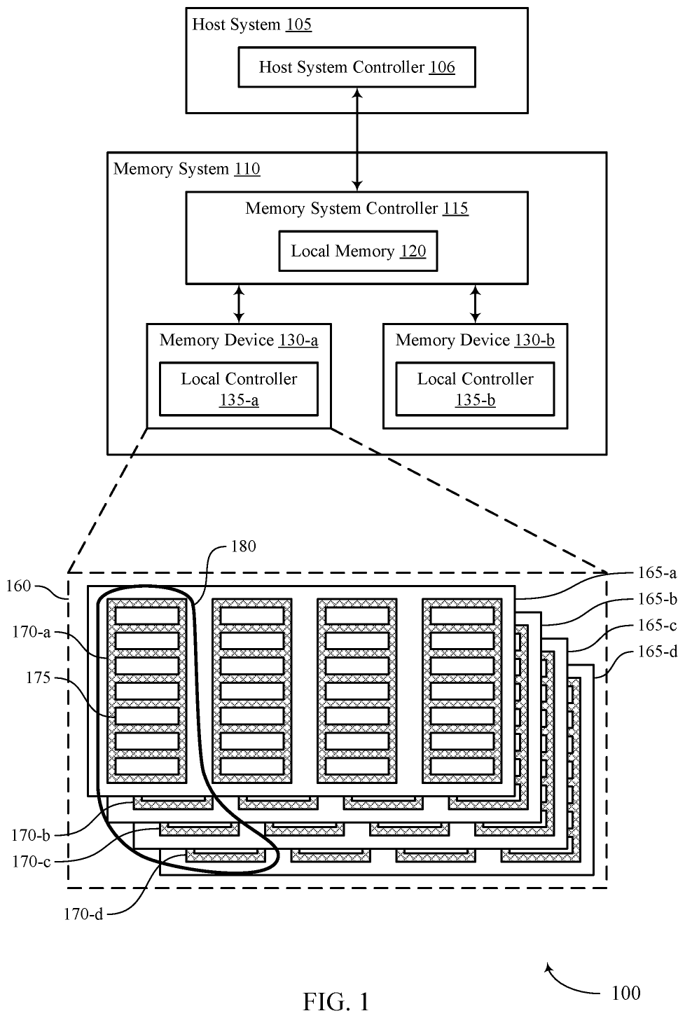

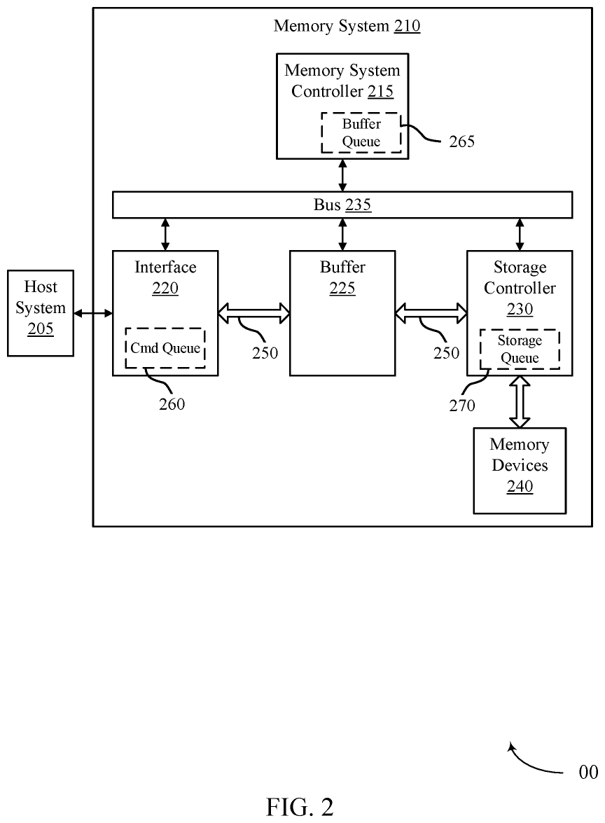

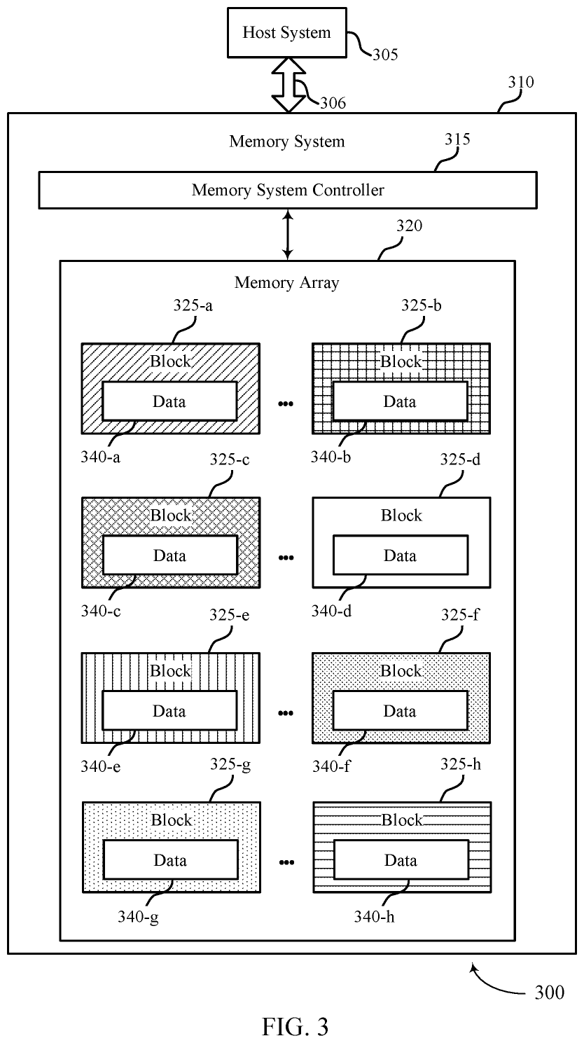

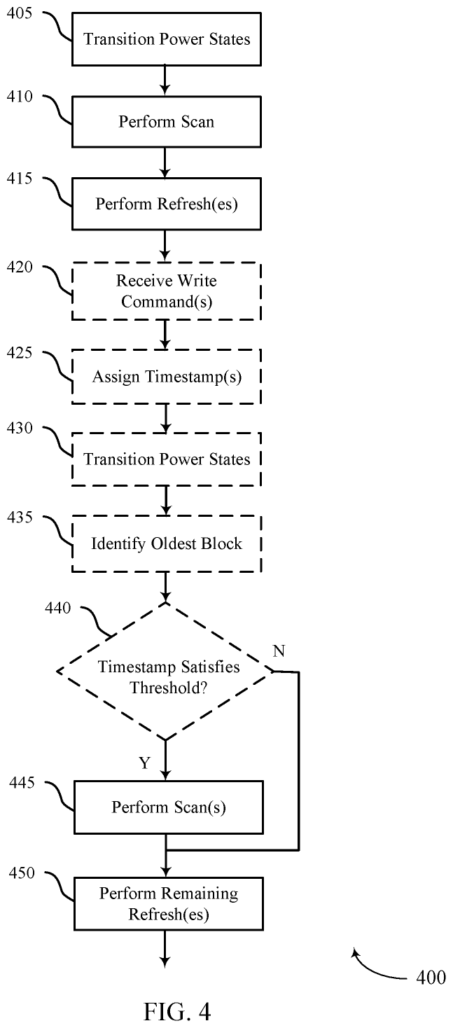

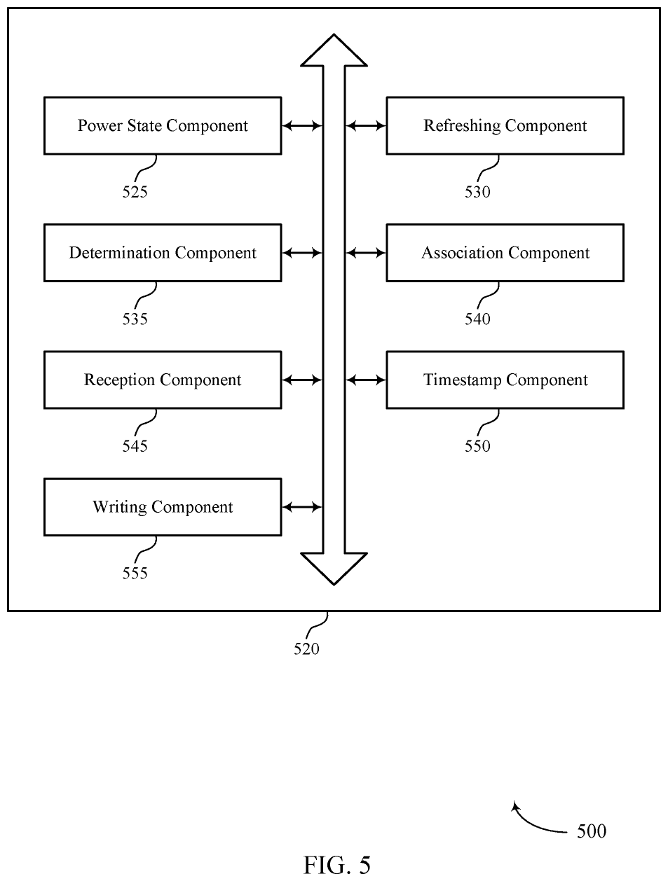

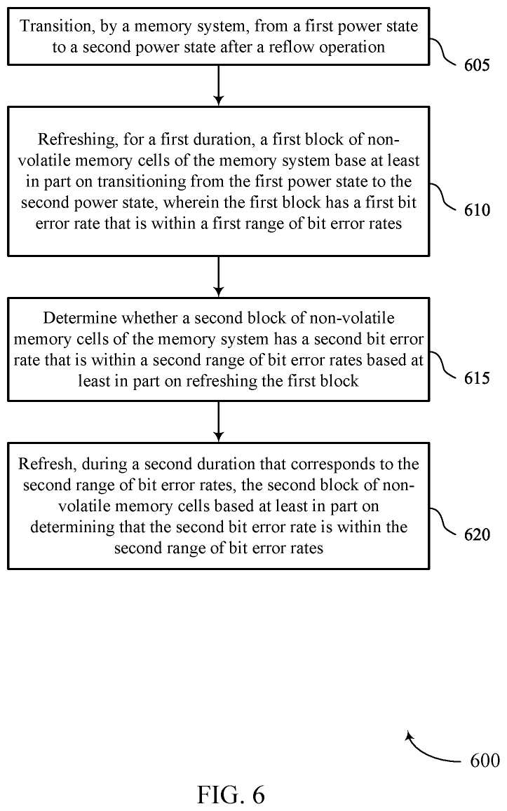

Features of the disclosure are initially described in the context of systems, devices, and circuits with reference to FIGS. 1 through 2. Features of the disclosure are described in the context of systems and process flow diagrams with reference to FIGS. 3 through 4. These and other features of the disclosure are further illustrated by and described in the context of an apparatus diagram and flowchart that relate to prioritizing refresh operations of a memory system with reference to FIGS. 5 through 6.

FIG. 1 illustrates an example of a system 100 that supports prioritizing refresh operations of a memory system in accordance with examples as disclosed herein. The system 100 includes a host system 105 coupled with a memory system 110.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other possibilities.

The system 100 may be included in a computing device such as a desktop computer, a laptop computer, a network server, a mobile device, a vehicle (e.g., airplane, drone, train, automobile, or other conveyance), an Internet of Things (IOT) enabled device, an embedded computer (e.g., one included in a vehicle, industrial equipment, or a networked commercial device), or any other computing device that includes memory and a processing device.

The system 100 may include a host system 105, which may be coupled with the memory system 110. In some examples, this coupling may include an interface with a host system controller 106, which may be an example of a controller or control component configured to cause the host system 105 to perform various operations in accordance with examples as described herein. The host system 105 may include one or more devices and, in some cases, may include a processor chipset and a software stack executed by the processor chipset. For example, the host system 105 may include an application configured for communicating with the memory system 110 or a device therein. The processor chipset may include one or more cores, one or more caches (e.g., memory local to or included in the host system 105), a memory controller (e.g., NVDIMM controller), and a storage protocol controller (e.g., peripheral component interconnect express (PCIe) controller, serial advanced technology attachment (SATA) controller). The host system 105 may use the memory system 110, for example, to write data to the memory system 110 and read data from the memory system 110. Although one memory system 110 is shown in FIG. 1, the host system 105 may be coupled with any quantity of memory systems 110.

The host system 105 may be coupled with the memory system 110 via at least one physical host interface. The host system 105 and the memory system 110 may, in some cases, be configured to communicate via a physical host interface using an associated protocol (e.g., to exchange or otherwise communicate control, address, data, and other signals between the memory system 110 and the host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a DIMM interface (e.g., DIMM socket interface that supports DDR), an Open NAND Flash Interface (ONFI), and a Low Power Double Data Rate (LPDDR) interface. In some examples, one or more such interfaces may be included in or otherwise supported between a host system controller 106 of the host system 105 and a memory system controller 115 of the memory system 110. In some examples, the host system 105 may be coupled with the memory system 110 (e.g., the host system controller 106 may be coupled with the memory system controller 115) via a respective physical host interface for each memory device 130 included in the memory system 110, or via a respective physical host interface for each type of memory device 130 included in the memory system 110.

The memory system 110 may include a memory system controller 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1, the memory system 110 may include any quantity of memory devices 130. Further, if the memory system 110 includes more than one memory device 130, different memory devices 130 within the memory system 110 may include the same or different types of memory cells.

The memory system controller 115 may be coupled with and communicate with the host system 105 (e.g., via the physical host interface) and may be an example of a controller or control component configured to cause the memory system 110 to perform various operations in accordance with examples as described herein. The memory system controller 115 may also be coupled with and communicate with memory devices 130 to perform operations such as reading data, writing data, erasing data, or refreshing data at a memory device 130—among other such operations—which may generically be referred to as access operations. In some cases, the memory system controller 115 may receive commands from the host system 105 and communicate with one or more memory devices 130 to execute such commands (e.g., at memory arrays within the one or more memory devices 130). For example, the memory system controller 115 may receive commands or operations from the host system 105 and may convert the commands or operations into instructions or appropriate commands to achieve the desired access of the memory devices 130. In some cases, the memory system controller 115 may exchange data with the host system 105 and with one or more memory devices 130 (e.g., in response to or otherwise in association with commands from the host system 105). For example, the memory system controller 115 may convert responses (e.g., data packets or other signals) associated with the memory devices 130 into corresponding signals for the host system 105.

The memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 105 and physical addresses (e.g., physical block addresses) associated with memory cells within the memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to the memory system controller 115. The memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 115 may also include a local memory 120. In some cases, the local memory 120 may include read-only memory (ROM) or other memory that may store operating code (e.g., executable instructions) executable by the memory system controller 115 to perform functions ascribed herein to the memory system controller 115. In some cases, the local memory 120 may additionally, or alternatively, include static random access memory (SRAM) or other memory that may be used by the memory system controller 115 for internal storage or calculations, for example, related to the functions ascribed herein to the memory system controller 115. Additionally, or alternatively, the local memory 120 may serve as a cache for the memory system controller 115. For example, data may be stored in the local memory 120 if read from or written to a memory device 130, and the data may be available within the local memory 120 for subsequent retrieval for or manipulation (e.g., updating) by the host system 105 (e.g., with reduced latency relative to a memory device 130) in accordance with a cache policy.

Although the example of the memory system 110 in FIG. 1 has been illustrated as including the memory system controller 115, in some cases, a memory system 110 may not include a memory system controller 115. For example, the memory system 110 may additionally, or alternatively, rely on an external controller (e.g., implemented by the host system 105) or one or more local controllers 135, which may be internal to memory devices 130, respectively, to perform the functions ascribed herein to the memory system controller 115. In general, one or more functions ascribed herein to the memory system controller 115 may, in some cases, be performed instead by the host system 105, a local controller 135, or any combination thereof. In some cases, a memory device 130 that is managed at least in part by a memory system controller 115 may be referred to as a managed memory device. An example of a managed memory device is a managed NAND (MNAND) device.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric random access memory (RAM) (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof.

Additionally, or alternatively, a memory device 130 may include one or more arrays of volatile memory cells. For example, a memory device 130 may include RAM memory cells, such as dynamic RAM (DRAM) memory cells and synchronous DRAM (SDRAM) memory cells.

In some examples, a memory device 130 may include (e.g., on a same die or within a same package) a local controller 135, which may execute operations on one or more memory cells of the respective memory device 130. A local controller 135 may operate in conjunction with a memory system controller 115 or may perform one or more functions ascribed herein to the memory system controller 115. For example, as illustrated in FIG. 1, a memory device 130-a may include a local controller 135-a and a memory device 130-b may include a local controller 135-b.

In some cases, a memory device 130 may be or include a NAND device (e.g., NAND flash device). A memory device 130 may be or include a die 160 (e.g., a memory die). For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of blocks 170, where each block 170 may include a respective set of pages 175, and each page 175 may include a set of memory cells.

In some cases, a NAND memory device 130 may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 165 may refer to groups of blocks 170, and in some cases, concurrent operations may be performed on different planes 165. For example, concurrent operations may be performed on memory cells within different blocks 170 so long as the different blocks 170 are in different planes 165. In some cases, an individual block 170 may be referred to as a physical block, and a virtual block 180 may refer to a group of blocks 170 within which concurrent operations may occur. For example, concurrent operations may be performed on blocks 170-a, 170-b, 170-c, and 170-d that are within planes 165-a, 165-b, 165-c, and 165-d, respectively, and blocks 170-a, 170-b, 170-c, and 170-d may be collectively referred to as a virtual block 180. In some cases, a virtual block may include blocks 170 from different memory devices 130 (e.g., including blocks in one or more planes of memory device 130-a and memory device 130-b). In some cases, the blocks 170 within a virtual block may have the same block address within their respective planes 165 (e.g., block 170-a may be “block 0” of plane 165-a, block 170-b may be “block 0” of plane 165-b, and so on). In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in a same page 175 may share (e.g., be coupled with) a common word line, and memory cells in a same string may share (e.g., be coupled with) a common digit line (which may alternatively be referred to as a bit line).

For some NAND architectures, memory cells may be read and programmed (e.g., written) at a first level of granularity (e.g., at the page level of granularity) but may be erased at a second level of granularity (e.g., at the block level of granularity). That is, a page 175 may be the smallest unit of memory (e.g., set of memory cells) that may be independently programmed or read (e.g., programed or read concurrently as part of a single program or read operation), and a block 170) may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may, in some cases, not be updated until the entire block 170 that includes the page 175 has been erased.

In some cases, to update some data within a block 170 while retaining other data within the block 170, the memory device 130 may copy the data to be retained to a new block 170 and write the updated data to one or more remaining pages of the new block 170. The memory device 130 (e.g., the local controller 135) or the memory system controller 115 may mark or otherwise designate the data that remains in the old block 170 as invalid or obsolete and may update a logical-to-physical (L2P) mapping table to associate the logical address (e.g., LBA) for the data with the new; valid block 170 rather than the old, invalid block 170. In some cases, such copying and remapping may be performed instead of erasing and rewriting the entire old block 170 due to latency or wearout considerations, for example. In some cases, one or more copies of an L2P mapping table may be stored within the memory cells of the memory device 130 (e.g., within one or more blocks 170 or planes 165) for use (e.g., reference and updating) by the local controller 135 or memory system controller 115.

In some cases, a memory system controller 115 or a local controller 135 may perform operations (e.g., as part of one or more media management algorithms) for a memory device 130, such as wear leveling, background refresh, garbage collection, scrub, block scans, health monitoring, or others, or any combination thereof. For example, within a memory device 130, a block 170 may have some pages 175 containing valid data and some pages 175 containing invalid data. To avoid waiting for all of the pages 175 in the block 170 to have invalid data in order to erase and reuse the block 170, an algorithm referred to as “garbage collection” may be invoked to allow the block 170 to be erased and released as a free block for subsequent write operations. Garbage collection may refer to a set of media management operations that include, for example, selecting a block 170 that contains valid and invalid data, selecting pages 175 in the block that contain valid data, copying the valid data from the selected pages 175 to new locations (e.g., free pages 175 in another block 170), marking the data in the previously selected pages 175 as invalid, and erasing the selected block 170. As a result, the quantity of blocks 170 that have been erased may be increased such that more blocks 170 are available to store subsequent data (e.g., data subsequently received from the host system 105).

In some cases, a memory system 110 may utilize a memory system controller 115 to provide a managed memory system that may include, for example, one or more memory arrays and related circuitry combined with a local (e.g., on-die or in-package) controller (e.g., local controller 135). An example of a managed memory system is a managed NAND (MNAND) system.

The system 100 may include any quantity of non-transitory computer readable media that support prioritizing refresh operations of a memory system. For example, the host system 105 (e.g., a host system controller 106), the memory system 110 (e.g., a memory system controller 115), or a memory device 130 (e.g., a local controller 135) may include or otherwise may access one or more non-transitory computer readable media storing instructions (e.g., firmware, logic, code) for performing the functions ascribed herein to the host system 105, the memory system 110, or a memory device 130. For example, such instructions, if executed by the host system 105 (e.g., by a host system controller 106), by the memory system 110 (e.g., by a memory system controller 115), or by a memory device 130 (e.g., by a local controller 135), may cause the host system 105, the memory system 110, or the memory device 130 to perform associated functions as described herein.

In some instances, upon transitioning power states (e.g., powering on) after a reflow process, the memory system 110 may identify one or more PSA blocks to refresh. For example, the memory system controller 115 may scan each of the PSA blocks of the memory array and identify a respective BER for each PSA block. According to the respective BERS, each PSA block may be prioritized for refreshing. For example, the memory system controller 115 may refresh the PSA blocks having relatively high BERs before refreshing the PSA blocks having relatively low BERs. By refreshing the PSA blocks having relatively high BERs upon transitioning power states, the memory system 110 may minimize system latency that would otherwise be incurred due to refreshing each of the PSA blocks at power-on.

Moreover, the memory system controller 115 may scan and refresh other PSA blocks at a different time (e.g., at a later time, after a subsequent power-on). For example, at a later time, the memory system controller 115 may execute a second scan operation on the PSA blocks to identify an updated BER for each PSA block. Based on the updated BERs, the memory system controller 115 may refresh the respective PSA blocks during a duration that is based on the respective BERs. For example, PSA blocks having a relatively high BER may be refreshed concurrent with one or more access operations being performed on a memory device 130. In other instances, PSA blocks having a relatively low BER may be refreshed during background operations. Accordingly, the memory system 110 may prioritize refresh operations on PSA blocks to minimize system latency and improve the system's overall performance and reliability.

FIG. 2 illustrates an example of a system 200 that supports prioritizing refresh operations of a memory system in accordance with examples as disclosed herein. The system 200 may be an example of a system 100 as described with reference to FIG. 1, or aspects thereof. The system 200 may include a memory system 210 configured to store data received from the host system 205 and to send data to the host system 205, if requested by the host system 205 using access commands (e.g., read commands or write commands). The system 200 may implement aspects of the system 100 as described with reference to FIG. 1. For example, the memory system 210 and the host system 205 may be examples of the memory system 110 and the host system 105, respectively.

The memory system 210 may include one or more memory devices 240 to store data transferred between the memory system 210 and the host system 205 (e.g., in response to receiving access commands from the host system 205). The memory devices 240 may include one or more memory devices as described with reference to FIG. 1. For example, the memory devices 240 may include NAND memory, PCM, self-selecting memory, 3D cross point or other chalcogenide-based memories, FERAM, MRAM, NOR (e.g., NOR flash) memory, STT-MRAM, CBRAM, RRAM, or OxRAM, among other examples.

The memory system 210 may include a storage controller 230 for controlling the passing of data directly to and from the memory devices 240 (e.g., for storing data, for retrieving data, for determining memory locations in which to store data and from which to retrieve data). The storage controller 230 may communicate with memory devices 240) directly or via a bus (not shown), which may include using a protocol specific to each type of memory device 240. In some cases, a single storage controller 230 may be used to control multiple memory devices 240 of the same or different types. In some cases, the memory system 210 may include multiple storage controllers 230 (e.g., a different storage controller 230 for each type of memory device 240). In some cases, a storage controller 230 may implement aspects of a local controller 135 as described with reference to FIG. 1.

The memory system 210 may include an interface 220 for communication with the host system 205, and a buffer 225 for temporary storage of data being transferred between the host system 205 and the memory devices 240. The interface 220, buffer 225, and storage controller 230 may support translating data between the host system 205 and the memory devices 240 (e.g., as shown by a data path 250), and may be collectively referred to as data path components.

Using the buffer 225 to temporarily store data during transfers may allow data to be buffered while commands are being processed, which may reduce latency between commands and may support arbitrary data sizes associated with commands. This may also allow bursts of commands to be handled, and the buffered data may be stored, or transmitted, or both (e.g., after a burst has stopped). The buffer 225 may include relatively fast memory (e.g., some types of volatile memory, such as SRAM or DRAM), or hardware accelerators, or both to allow fast storage and retrieval of data to and from the buffer 225. The buffer 225 may include data path switching components for bi-directional data transfer between the buffer 225 and other components.

A temporary storage of data within a buffer 225 may refer to the storage of data in the buffer 225 during the execution of access commands. For example, after completion of an access command, the associated data may no longer be maintained in the buffer 225 (e.g., may be overwritten with data for additional access commands). In some examples, the buffer 225 may be a non-cache buffer. For example, data may not be read directly from the buffer 225 by the host system 205. In some examples, read commands may be added to a queue without an operation to match the address to addresses already in the buffer 225 (e.g., without a cache address match or lookup operation).

The memory system 210 also may include a memory system controller 215 for executing the commands received from the host system 205, which may include controlling the data path components for the moving of the data. The memory system controller 215 may be an example of the memory system controller 115 as described with reference to FIG. 1. A bus 235 may be used to communicate between the system components.

In some cases, one or more queues (e.g., a command queue 260), a buffer queue 265, a storage queue 270) may be used to control the processing of access commands and the movement of corresponding data. This may be beneficial, for example, if more than one access command from the host system 205 is processed concurrently by the memory system 210. The command queue 260, buffer queue 265, and storage queue 270) are depicted at the interface 220, memory system controller 215, and storage controller 230, respectively, as examples of a possible implementation. However, queues, if implemented, may be positioned anywhere within the memory system 210.

Data transferred between the host system 205 and the memory devices 240 may be conveyed along a different path in the memory system 210 than non-data information (e.g., commands, status information). For example, the system components in the memory system 210 may communicate with each other using a bus 235, while the data may use the data path 250) through the data path components instead of the bus 235. The memory system controller 215 may control how and if data is transferred between the host system 205 and the memory devices 240 by communicating with the data path components over the bus 235 (e.g., using a protocol specific to the memory system 210).

If a host system 205 transmits access commands to the memory system 210, the commands may be received by the interface 220 (e.g., according to a protocol, such as a UFS protocol or an eMMC protocol). Thus, the interface 220 may be considered a front end of the memory system 210. After receipt of each access command, the interface 220 may communicate the command to the memory system controller 215 (e.g., via the bus 235). In some cases, each command may be added to a command queue 260 by the interface 220 to communicate the command to the memory system controller 215.

The memory system controller 215 may determine that an access command has been received based on the communication from the interface 220. In some cases, the memory system controller 215 may determine the access command has been received by retrieving the command from the command queue 260. The command may be removed from the command queue 260 after it has been retrieved (e.g., by the memory system controller 215). In some cases, the memory system controller 215 may cause the interface 220 (e.g., via the bus 235) to remove the command from the command queue 260.

After a determination that an access command has been received, the memory system controller 215 may execute the access command. For a read command, this may include obtaining data from one or more memory devices 240) and transmitting the data to the host system 205. For a write command, this may include receiving data from the host system 205 and moving the data to one or more memory devices 240. In either case, the memory system controller 215 may use the buffer 225 for, among other things, temporary storage of the data being received from or sent to the host system 205. The buffer 225 may be considered a middle end of the memory system 210. In some cases, buffer address management (e.g., pointers to address locations in the buffer 225) may be performed by hardware (e.g., dedicated circuits) in the interface 220, buffer 225, or storage controller 230.

To process a write command received from the host system 205, the memory system controller 215 may determine if the buffer 225 has sufficient available space to store the data associated with the command. For example, the memory system controller 215 may determine (e.g., via firmware, via controller firmware), an amount of space within the buffer 225 that may be available to store data associated with the write command.

In some cases, a buffer queue 265 may be used to control a flow of commands associated with data stored in the buffer 225, including write commands. The buffer queue 265 may include the access commands associated with data currently stored in the buffer 225. In some cases, the commands in the command queue 260 may be moved to the buffer queue 265 by the memory system controller 215 and may remain in the buffer queue 265 while the associated data is stored in the buffer 225. In some cases, each command in the buffer queue 265 may be associated with an address at the buffer 225. For example, pointers may be maintained that indicate where in the buffer 225 the data associated with each command is stored. Using the buffer queue 265, multiple access commands may be received sequentially from the host system 205 and at least portions of the access commands may be processed concurrently.

If the buffer 225 has sufficient space to store the write data, the memory system controller 215 may cause the interface 220 to transmit an indication of availability to the host system 205 (e.g., a “ready to transfer” indication), which may be performed in accordance with a protocol (e.g., a UFS protocol, an eMMC protocol). As the interface 220 receives the data associated with the write command from the host system 205, the interface 220 may transfer the data to the buffer 225 for temporary storage using the data path 250. In some cases, the interface 220 may obtain (e.g., from the buffer 225, from the buffer queue 265) the location within the buffer 225 to store the data. The interface 220 may indicate to the memory system controller 215 (e.g., via the bus 235) if the data transfer to the buffer 225 has been completed.

After the write data has been stored in the buffer 225 by the interface 220, the data may be transferred out of the buffer 225 and stored in a memory device 240, which may involve operations of the storage controller 230. For example, the memory system controller 215 may cause the storage controller 230 to retrieve the data from the buffer 225 using the data path 250 and transfer the data to a memory device 240. The storage controller 230 may be considered a back end of the memory system 210. The storage controller 230 may indicate to the memory system controller 215 (e.g., via the bus 235) that the data transfer to one or more memory devices 240 has been completed.

In some cases, a storage queue 270 may support a transfer of write data. For example, the memory system controller 215 may push (e.g., via the bus 235) write commands from the buffer queue 265 to the storage queue 270 for processing. The storage queue 270 may include entries for each access command. In some examples, the storage queue 270 may additionally include a buffer pointer (e.g., an address) that may indicate where in the buffer 225 the data associated with the command is stored and a storage pointer (e.g., an address) that may indicate the location in the memory devices 240 associated with the data. In some cases, the storage controller 230 may obtain (e.g., from the buffer 225, from the buffer queue 265, from the storage queue 270) the location within the buffer 225 from which to obtain the data. The storage controller 230 may manage the locations within the memory devices 240 to store the data (e.g., performing wear-leveling, performing garbage collection). The entries may be added to the storage queue 270 (e.g., by the memory system controller 215). The entries may be removed from the storage queue 270 (e.g., by the storage controller 230, by the memory system controller 215) after completion of the transfer of the data.

To process a read command received from the host system 205, the memory system controller 215 may determine if the buffer 225 has sufficient available space to store the data associated with the command. For example, the memory system controller 215 may determine (e.g., via firmware, via controller firmware), an amount of space within the buffer 225 that may be available to store data associated with the read command.

In some cases, the buffer queue 265 may support buffer storage of data associated with read commands in a similar manner as discussed with respect to write commands. For example, if the buffer 225 has sufficient space to store the read data, the memory system controller 215 may cause the storage controller 230 to retrieve the data associated with the read command from a memory device 240 and store the data in the buffer 225 for temporary storage using the data path 250. The storage controller 230 may indicate to the memory system controller 215 (e.g., via the bus 235) when the data transfer to the buffer 225 has been completed.

In some cases, the storage queue 270 may be used to aid with the transfer of read data. For example, the memory system controller 215 may push the read command to the storage queue 270 for processing. In some cases, the storage controller 230 may obtain (e.g., from the buffer 225, from the storage queue 270) the location within one or more memory devices 240 from which to retrieve the data. In some cases, the storage controller 230 may obtain (e.g., from the buffer queue 265) the location within the buffer 225 to store the data. In some cases, the storage controller 230 may obtain (e.g., from the storage queue 270) the location within the buffer 225 to store the data. In some cases, the memory system controller 215 may move the command processed by the storage queue 270 back to the command queue 260.

Once the data has been stored in the buffer 225 by the storage controller 230, the data may be transferred from the buffer 225 and sent to the host system 205. For example, the memory system controller 215 may cause the interface 220 to retrieve the data from the buffer 225 using the data path 250 and transmit the data to the host system 205 (e.g., according to a protocol, such as a UFS protocol or an eMMC protocol). For example, the interface 220 may process the command from the command queue 260 and may indicate to the memory system controller 215 (e.g., via the bus 235) that the data transmission to the host system 205 has been completed.

The memory system controller 215 may execute received commands according to an order (e.g., a first-in-first-out order, according to the order of the command queue 260). For each command, the memory system controller 215 may cause data corresponding to the command to be moved into and out of the buffer 225, as discussed herein. As the data is moved into and stored within the buffer 225, the command may remain in the buffer queue 265. A command may be removed from the buffer queue 265 (e.g., by the memory system controller 215) if the processing of the command has been completed (e.g., if data corresponding to the access command has been transferred out of the buffer 225). If a command is removed from the buffer queue 265, the address previously storing the data associated with that command may be available to store data associated with a new command.

In some examples, the memory system controller 215 may be configured for operations associated with one or more memory devices 240. For example, the memory system controller 215 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., LBAs) associated with commands from the host system 205 and physical addresses (e.g., physical block addresses) associated with memory cells within the memory devices 240. For example, the host system 205 may issue commands indicating one or more LBAs and the memory system controller 215 may identify one or more physical block addresses indicated by the LBAs. In some cases, one or more contiguous LBAs may correspond to noncontiguous physical block addresses. In some cases, the storage controller 230 may be configured to perform one or more of the described operations in conjunction with or instead of the memory system controller 215. In some cases, the memory system controller 215 may perform the functions of the storage controller 230 and the storage controller 230 may be omitted.

In some instances, upon transitioning power states (e.g., powering on) after a reflow process, the memory system 210 may identify one or more PSA blocks to refresh. For example, the memory system controller 215 may scan each of the PSA blocks of the memory array and identify a respective BER for each PSA block. According to the respective BERs, each PSA block may be prioritized for refreshing. For example, the memory system controller 215 may refresh the PSA blocks having relatively high BERs before refreshing the PSA blocks having relatively low BERs. By refreshing the PSA blocks having relatively high BERs upon transitioning power states, the memory system 210 may minimize system latency that would otherwise be incurred due to refreshing each of the PSA blocks at power-on.

Moreover, the memory system controller 215 may scan and refresh other PSA blocks at a different time (e.g., at a later time, after a subsequent power-on). For example, at a later time, the memory system controller 215 may execute a second scan operation on the PSA blocks to identify an updated BER for each PSA block. Based on the updated BERs, the memory system controller 215 may refresh the respective PSA blocks during a duration that is based on the respective BERs. For example, PSA blocks having a relatively high BER may be refreshed concurrent with one or more access operations being performed on a memory device 240. In other instances, PSA blocks having a relatively low BER may be refreshed during background operations. Accordingly, the memory system 210 may prioritize refresh operations on PSA blocks to minimize system latency and improve the system's overall performance and reliability.

FIG. 3 illustrates an example of a system 300 that supports prioritizing refresh operations of a memory system in accordance with examples as disclosed herein. The system 300 may include a host system 305 and a memory system 310. In some cases, the host system 305 and the memory system 310 may represent a host system 105 or 205 and a memory system 110 or 210, respectively, as described with reference to FIG. 1 and FIG. 2. In some examples, the host system 305 may be coupled with the memory system 310 via an interface 306. The memory system 310 may be configured to refresh PSA blocks with relatively high BERs at power-on (e.g., at a first power-on), and may refresh the same or other PSA blocks at a later time, which may reduce latency at power-on and improve the overall performance and reliability of the memory system 310.

The memory system 310 may include a memory array 320 that includes one or more blocks 325 of non-volatile memory cells. For example, the memory array 320 may include at least blocks 325-a, 325-b, 325-c, 325-d, 325-e, 325-f, 325-g, 325-h and any quantity of intervening blocks 325 in between. For exemplary purposes only, the blocks 325-a. 325-b, 325-c, 325-d, and 325-e may represent PSA blocks and the blocks 325-f and 325-g may represent non-PSA blocks (e.g., a normal block, a fresh block, a block not pre-loaded with data). As used herein, a PSA block may refer to a block that is pre-loaded with data before one or more manufacturing operations (e.g., before the memory array 320 is soldered to the memory system 310).

In some instances, the blocks 325 may represent physical blocks of memory cells. For example, the memory cells of block 325-a may include memory cells storing one bit of data (e.g., one or more single-level cells (SLCs)), two bits of data (e.g., one or more multi-level cells (MLCs)), three bits of data (e.g., one or more triple-level cells (TLCs)), or four bits of data (e.g., one or more quad-level cells (QLCs)). Additionally, each of the memory cells of the respective blocks 325-b, 325-c, 325-d, 325-e, 325-f, 325-g, 325-h may include memory cells configured in the same or similarly (e.g., memory cells storing one or more bits of data). Each of the blocks 325 may store respective data. For example, the block 325-a may store data 340-a, the block 325-b may store data 340-b, the block 325-c may store data 340-c, the block 325-d may store data 340-d, the block 325-e may store data 340-e, the block 325-f may store data 340-f, the block 325-g may store data 340-g, and the block 325-h may store data 340-h.

In some cases, the blocks 325 of the memory array 320 may be written with data prior to being packaged in the memory system 310. For example, each of the PSA blocks 325-a and 325-b may be written with data before a reflow process. During a reflow process, a manufacturing system may attach the memory array 320 to a circuit board or other component of the memory system 310. In some cases, the manufacturing system may use a soldering process to attach the memory array 320 to one or more system components. The soldering process may expose the memory array 320 to relatively high thermal stresses (e.g., temperatures), which may affect the PSA blocks and the data stored therein.

In some instances, the memory system 310 may perform a scan operation upon powering on (e.g., booting up, transitioning power states) after the reflow process is complete. For example, the memory system 310 may transition from a first power state (e.g., an “off state,” a low power state, a reduced power state) to a second power state (e.g., an “on” state, a normal power state) for a first time after a reflow operation. In some cases, the memory system 310 may transition power states during a first duration.

In some instances, the memory system 310 may perform a scan operation during or after the first power-on. For example, the memory system controller 315 may be configured to scan at least the PSA block 325-a, 325-b, 325-c, 325-d, and 325-e of the memory array 320. In some examples, the scan operation may identify a BER for each PSA block, and the memory system 310 may refresh one or more blocks 325 according to the respective BERs. For example, a block 325 having a relatively high BER may be refreshed, whereas a block having a relatively low BER may be refreshed at a later time. By way of example, the PSA block 325-a may be associated with a relatively high BER, whereas the PSA block 325-b may be associated with a relatively low BER.

During the scan operation, the memory system controller 315 may generate a refresh list (e.g., table) of PSA blocks based on the respective BER of each block 325. For example, while generating the refresh list, the memory system controller 315 may sort (e.g., organize, order) the scanned PSA blocks from the highest BER to the lowest BER, from the lowest BER to the highest BER, or in another organizational format. In some cases, each entry of the refresh list may be an address (e.g., logical block address (LBA)) associated with a respective PSA block). Additionally, each entry of the refresh list may be associated with a respective BER, health state, or level of urgency for performing a refresh operation. In some cases, the memory system controller 315 may refrain from adding one or more PSA blocks to the refresh list. For example, the PSA block 325-b, among other PSA blocks, may be associated with a relatively low BER (e.g., very few errors per unit of time, zero errors per unit of time, or the like), and thus may not be added to the refresh list.

The memory system controller 315 may divide the refresh list into two or more sections (e.g., ranges), and each section of the refresh list may be associated with a respective range of BERs. For example, a first section may be associated with BERs equal to or greater than a threshold (e.g., a threshold value) and a second section may be associated with BERs less than the threshold. In some cases, the memory system controller 315 may divide the refresh list into any quantity of sections or ranges.

In some cases, the memory system 310 may be configured to refresh the scanned PSA blocks during the first duration according to the refresh list. For example, the memory system controller 315 may be configured to refresh the PSA blocks having BERs that are greater than or equal to the threshold, as these blocks 325 may pose the greatest risk of failure (e.g., catastrophic failure) to the memory system 310. For example, the memory system controller 315 may refresh the PSA block 325-a. Accordingly, the memory system controller 315 may refresh each of the PSA blocks having BERs that are greater than or equal to the threshold after the memory system 310 transitions power states, but before the memory system 310 begins processing commands received from the host system 305.

In some cases, the memory system controller 315 may refrain from refreshing one or more PSA blocks upon the memory system 310 transitioning power states. For example, the memory system controller 315 refrain from refreshing the PSA blocks 325-b. Additionally, or alternatively, the memory system controller 315 may refrain from refreshing any PSA blocks having a BER that is less than the threshold due to the memory system 310 having a relatively limited quantity of system resources during power-on (e.g., time, power, bandwidth).

In some cases, refreshing a given PSA block 325 during the first duration may include moving (e.g., transferring, copying) data from the PSA block 325 to a non-PSA block (e.g., a fresh block, a normal block), such as the block 325-f. For example, when the PSA block 325-a is refreshed, the data 340-a may be moved from the PSA block 325-a to the block 325-f. In some instances, the memory system controller 315 may update a mapping (e.g., a L2P mapping) based on refreshing the data 340-a.

The memory system 310 may execute (e.g., re-execute) a second scan operation after the first refresh operation is complete. For example, the memory system 310 may execute the second scan operation at a critical time defined by the memory system 310 (e.g., device controlled mode) or by the host system 305 (e.g., e.g., host controlled mode). In some cases, the critical time may be indicated by a command (e.g., a command transmitted from the host system 305 to the memory system 310 via the interface 306). For example, the host system 305 may provide real-time clock (RTC) information to the memory system 310, and the RTC information may indicate a critical time to perform the scan operation. In some cases, the critical time may be based on a duration of time after the power-on, the previous refresh operation, the previous scan operation, the receiving of the RTC information, or another event. In other examples, the critical time may be a static time determined by the host system 305 irrespective of the aforementioned events.

In some cases, the critical time may be determined by the memory system controller 315 according to a post-reflow process. In some cases, the post-reflow process may happen after one of the first scan operation, the first refresh operation, or both. The memory system controller 315 may receive one or more write commands from the host system 305. For example, the write command may be associated with writing data to a respective block 325 of the memory array 320. Based on the write command, the memory system controller 315 may access (e.g., open) a respective block 325 to execute the write operation requested by the host system 305.

Upon accessing the block 325, the memory system controller 315 may write (e.g., add, store), a timestamp associated with opening the block. For example, when the host system 305 requests to write to the block 325, the memory system controller may add a timestamp to the block 325 (or to another location of the memory system 310) indicating the time at which the block 325 was accessed. For example, host system 305 may request to write to the block 325-g and the memory system controller 315 may add a first timestamp to the block 325-g indicating the time at which the block 325-g was accessed. As described herein, the block 325-g may be a non-PSA block.

After the post-reflow process, the memory system 305 may transition power states for a second time (e.g., a subsequent time). That is, the memory system 310 may power on for at least a second time. For example, the memory system 310 may transition from the second power state (e.g., an “on state,” normal power state) to the first power state (e.g., an “off state,” low power state, reduced power state), and back to the second power state.

Upon the second power-on, the memory system controller 315 may identify the oldest block 325 (e.g., the block 325 that was accessed the longest duration ago) according to the respective timestamps. For example, the oldest timestamp may be associated with the first block 325 accessed after the last refresh operation. Alternatively, the blocks 325 may be accessed more than once and the respective timestamps may be overwritten during each access operation. By way of example, the oldest block 325 may be the block 325-g.

The memory system controller 315 may perform a scan operation on the oldest identified block 325 (e.g., block 325-g). In some examples, during or after the scan operation, the memory system controller 315 may compare the BER of the oldest identified block 325 with a threshold value (e.g., a second threshold value). For example, the threshold value may be a maximum quantity of errors per unit of time allowed by the memory system 310. If the BER of the oldest identified block does not satisfy the threshold (e.g., the BER is less than the threshold), the memory system controller 315 may refrain from executing a second scan operation on the PSA blocks of the memory array 320. For example, the memory system controller 315 may resume other operations (e.g., access operations) until another critical time is reached.

Alternatively, if the BER of the oldest identified block 325 satisfies the threshold (e.g., the BER is greater than or equal to the threshold), the memory system controller 315 may execute (e.g., re-execute) a second scan operation on the PSA blocks of the memory array 320). In some cases, the second scan operation may be the same as the first scan operation. For example, the memory system controller 315 may re-scan the PSA blocks 325-b, 325-c, 325-d, and 325-e of memory array 320) and a may determine a new (e.g., an updated) BER for each of the PSA blocks. In some cases, the new BER may be the same as the previous BER. Alternatively, the BER of a given PSA block may have changed. For example, a PSA block with a relatively high BER during the first scan operation may have a relatively low BER during the second scan operation. Alternatively, a PSA block with a relatively low BER during the first scan operation (e.g., PSA block 325-b) may have a relatively high BER during the second scan operation. For example, PSA blocks 325 which were not refreshed during the first duration may experience a gradual increase in BER between the two scan operations (e.g., due to wear over time).

Based on the first or second scan operation, the memory system controller 315 may define an urgency of each PSA block based on its respective BER. For example, the PSA block 325-c may have a relatively low BER within a normal threshold range and may be associated with a “normal” urgency. Additionally, the PSA block 325-d may have a relatively higher BER than the block 325-c within a critical threshold range and may be associated with a “critical” urgency. Lastly, the PSA block 325-e may have a relatively high BER within an urgent threshold range and may be associated with an “urgent” urgency. Each level of urgency may be defined by a respective refresh cadence (e.g., frequency), and the duration during which a refresh operation is performed on the block 325. For example, PSA blocks having a “normal” urgency (e.g., the PSA block 325-c) may be refreshed during background operations. Accordingly, refreshing such PSA blocks may have little or no impact on read or write performance (e.g., user experience) of the memory system 310.

PSA blocks having a “critical” urgency (e.g., PSA block 325-d) may be refreshed during write operations. That is, critical PSA blocks may be refreshed concurrent with one or more ongoing write operations. In some instances, the memory system controller 315 may be able to adjust the cadence between refreshing a critical block and writing data to the memory array 320 based on system bandwidth. For example, when several PSA blocks have a critical urgency, the memory system controller 315 may prioritize performing refresh operations. In other examples, when several write commands are being processed, the memory system controller 315 may prioritize performing write operations.

PSA blocks having an “urgent” urgency (e.g., PSA block 325-e) may be refreshed during read operations and write operations. That is, critical PSA blocks may be refreshed concurrent with one or more ongoing read operations, write operations, or both. In some instances, the memory system controller 315 may be able to adjust the cadence between refreshing a critical block and reading data from or writing data to the memory array 320 based on system bandwidth. For example, when several PSA blocks have a critical urgency, the memory system controller 315 may prioritize performing refresh operations. In other examples, when several read commands, write commands, or both are being processed, the memory system controller 315 may prioritize performing the access operations.

After associating each of the scanned PSA blocks 325-c, 325-d, and 325-e with a respective urgency, the memory system controller 315 may refresh the PSA blocks according to their respective urgencies. For example, refreshing PSA blocks associated with a “normal” urgency may occur during a first duration, such as a period of idle time (e.g., a duration of time when no other access operations are occurring or when relatively few access operations are occurring). Additionally or alternatively, refreshing PSA blocks associated with a “critical” urgency may occur during the first duration, a second duration, or both, and the second duration may be during a write operation. Similarly, refreshing PSA blocks associated with an “urgent” urgency may occur during the first duration, the second duration, or both, and the second duration may be during a write operation or a read operation. By prioritizing refreshing PSA blocks as described herein, the memory system 310 may reduce latency at power-on, and thus its overall performance may be improved.

FIG. 4 illustrates an example of a process flow diagram 400 that supports prioritizing refresh operations of a memory system in accordance with examples as disclosed herein. In some examples, the process flow diagram 400 may be implemented by one or more aspects of the systems (e.g., the memory systems) as described with reference to FIGS. 1 through 3. For instance, the process flow diagram 400 may be implemented by a memory system 110 as described with reference to FIG. 1, a memory system 210 as described with reference to FIG. 2, or a memory system 310 as described with reference to FIG. 3. The memory system may be configured to refresh PSA blocks with relatively high BERs at power-on (e.g., at a first power-on), and may refresh the same or other PSA blocks at a later time, which may reduce latency at power-on and improve the overall performance and reliability of the memory system.

At 405, a memory system (e.g., the memory system 310 as described with reference to FIG. 3) may transition power states (e.g., the memory system may power-on). As described herein, the memory system may transition from a relatively low power state (e.g., an off state, a low power state, a hibernate state) to a relatively higher power state (e.g., an on state, a normal power state). In some instances, the memory system may transition power states for a first time (e.g., after being manufactured or after a reflow process).

At 410, the memory system may perform a scan operation after the first power-on. For example, the memory system controller may scan each PSA block of a memory array and identify a BER for each PSA block. The memory system controller may sort (e.g., organize, order) the scanned PSA blocks from the highest BER to the lowest BER, from the lowest BER to the highest BER, or in another organizational format.

At 415, the memory system may refresh one or more PSA blocks after performing the scan. For example, the memory system may prioritize refreshing PSA blocks with a relatively high BER. As described herein, the BER of the PSA blocks may be compared with a threshold and, based on whether the PSA of a respective block satisfies the threshold, a PSA block may be refreshed. For example, PSA blocks having a BER that satisfy the threshold may be refreshed, whereas PSA blocks having a BER that does not satisfy the threshold may not be refreshed (e.g., may not be refreshed at this time). In some instances, the memory system controller may refrain from refreshing one or more PSA blocks due to the memory system having relatively limited resources, or to mitigate any additional latency that refreshing the PSA blocks would cause.

At 420, the memory system may receive one or more write commands from the host system (e.g., the host system 305 as described with reference to FIG. 3). For example, each of the write commands may be associated with data to be written to one or more blocks (e.g., one or more non-PSA blocks) of a memory array. Based on the write commands, the memory controller may access (e.g., open) the respective block to execute the write operation requested by the host system.

At 425, the memory system may assign a timestamp to each block associated with a write command. For example, when a respective block (e.g., block 325-g as described with reference to FIG. 3) is open to perform the write operation, the memory system controller may assign a timestamp to the block. In some cases, if a block is written to more than once, a prior timestamp may be overwritten to indicate the most recent write operation.

At 430, the memory system may perform a second power state transition. For example, the memory system may have previously transitioned from the second power state (e.g., an “on state,” normal power state) to the first power state (e.g., an “off state,” low power state, reduced power state). Thus, at 430, the memory system may transition back to the second power state.

At 435, upon the second power-on, the memory system may identify the block having the oldest timestamp (e.g., the oldest non-PSA block) on the respective timestamps.

At 440), the memory system controller may determine whether the timestamp satisfies a threshold value. If the timestamp satisfies the threshold value, the memory system controller may assume that a long enough duration has passed since the last refresh operation and thus may rescan the PSA blocks, as described with reference to step 445, to determine the respective BERs of each PSA block. If the timestamp does not satisfy the threshold value, the memory system controller may refrain from rescanning the PSA blocks and may refresh one or more of the remaining PSA blocks, as described with reference to step 450.

At 445, if the timestamp of the oldest block satisfies the threshold value, the memory system may execute (e.g., re-execute) a second scan operation on the PSA blocks. In some cases, the second scan operation may be the same as the first scan operation. Additionally, in some cases, the BERs of one or more PSA blocks may be the same as its previous BER, or may be different (e.g., greater than, less than) its previous BER.

At 450, following the second scan operation, the memory system may refresh one or more of the PSA blocks according to an urgency of a respective block. Based on the second scan operation, the memory system controller may define an urgency of each PSA block based on its respective BER. For example, a first PSA block may have a relatively low BER and may be associated with a “normal” urgency. Additionally, a second PSA block may have a relatively higher BER than the first PSA block and may be associated with a “critical” urgency. Lastly, a third PSA block may have a relatively high BER and may be associated with an “urgent” urgency. If the timestamp of the oldest block does not satisfy the threshold value, and the second scan operation does not occur, the memory system may refresh one or more of the remaining PSA blocks based on the priority of the first scan and the first refresh. For example, one or more of the PSA blocks which were not refreshed during the first refresh (e.g., PSA blocks having a BER that did not satisfy the threshold) may now be refreshed.

Each level of urgency may be defined by a respective refresh cadence (e.g., frequency), and the duration during which a refresh operation is performed on the block. For example, PSA blocks having a “normal” urgency may be refreshed during background operations, whereas PSA blocks having “critical” urgencies may be refreshed during write operations and PSA blocks having “urgent” urgencies may be refreshed during read and write operations. By prioritizing refreshing PSA blocks as described herein, the memory system 310 may reduce latency at power-on, and thus its overall performance may be improved.

FIG. 5 illustrates a block diagram 500 of a memory system 520 that supports prioritizing refresh operations of a memory system in accordance with examples as disclosed herein. The memory system 520 may be an example of aspects of a memory system as described with reference to FIGS. 1 through 4. The memory system 520, or various components thereof, may be an example of means for performing various aspects of prioritizing refresh operations of a memory system as described herein. For example, the memory system 520 may include a power state component 525, a refreshing component 530, a determination component 535, an association component 540, a reception component 545, a timestamp component 550, a writing component 555, or any combination thereof. Each of these components may communicate, directly or indirectly, with one another (e.g., via one or more buses).

The power state component 525 may be configured as or otherwise support a means for transitioning, by a memory system, from a first power state to a second power state after a reflow operation. The refreshing component 530 may be configured as or otherwise support a means for refreshing, for a first duration, a first block of non-volatile memory cells of the memory system based at least in part on transitioning from the first power state to the second power state, where the first block has a first bit error rate that is within a first range of bit error rates. The determination component 535 may be configured as or otherwise support a means for determining whether a second block of non-volatile memory cells of the memory system has a second bit error rate that is within a second range of bit error rates based at least in part on refreshing the first block. In some examples, the refreshing component 530 may be configured as or otherwise support a means for refreshing, during a second duration that corresponds to the second range of bit error rates, the second block of non-volatile memory cells based at least in part on determining that the second bit error rate is within the second range of bit error rates.

In some examples, the association component 540 may be configured as or otherwise support a means for associating the first block of non-volatile memory cells with the first range of bit error rates based at least in part on transitioning from the first power state to the second power state, where refreshing the first block of non-volatile memory cells for the first duration is based at least in part on associating the first block of non-volatile memory cells with the first range of bit error rates.

In some examples, the determination component 535 may be configured as or otherwise support a means for determining that a third block of non-volatile memory cells of the memory system has a third bit error rate that is within a third range of bit error rates. In some examples, the refreshing component 530 may be configured as or otherwise support a means for refraining from refreshing, for the first duration, the third block of non-volatile memory cells based at least in part on determining that the third bit error rate of the third block is within the third range of bit error rates.

In some examples, the reception component 545 may be configured as or otherwise support a means for receiving a write command associated with the second block of non-volatile memory cells. In some examples, the timestamp component 550 may be configured as or otherwise support a means for assigning a timestamp to the second block of non-volatile memory cells based at least in part on receiving the write command, where determining whether the second block of non-volatile memory cells has the second bit error rate is based at least in part on assigning the timestamp.

In some examples, the power state component 525 may be configured as or otherwise support a means for transitioning, by the memory system for a second time, from the first power state to the second power state. In some examples, the determination component 535 may be configured as or otherwise support a means for determining that the second block of non-volatile memory cells has the second bit error rate based at least in part on the timestamp and transitioning from the first power state to the second power state. In some examples, the determination component 535 may be configured as or otherwise support a means for determining that the second bit error rate satisfies a threshold value based at least in part on determining that the second block of non-volatile memory cells has the second bit error rate.

In some examples, the association component 540 may be configured as or otherwise support a means for associating the second block of non-volatile memory cells with the second range of bit error rates based at least in part on determining that the second bit error rate satisfies the threshold value, where the second block of non-volatile memory cells is refreshed during the second duration based at least in part on associating the second block of non-volatile memory cells with the second range of bit error rates.

In some examples, the reception component 545 may be configured as or otherwise support a means for receiving a command from a host system based at least in part on determining that the second bit error rate satisfies the threshold value, where the command indicates a third duration for associating the second block of non-volatile memory cells with the second range of bit error rates, where the third duration occurs after the first duration and before the second duration.

In some examples, associating the second block of non-volatile memory cells with the second range of bit error rates occurs absent receiving a command from a host system.

In some examples, the determination component 535 may be configured as or otherwise support a means for determining that a fourth block of non-volatile memory cells of the memory system has a fourth bit error rate that is within a fourth range of bit error rates based at least in part on determining whether the second block of non-volatile memory cells of the memory system has the second bit error rate. In some examples, the refreshing component 530 may be configured as or otherwise support a means for refreshing, during a fourth duration that corresponds to the fourth range of bit error rates, the fourth block of non-volatile memory cells based at least in part on determining that the fourth bit error rate is within the fourth range of bit error rates.

In some examples, the fourth duration is associated with a duration when the memory system is performing a read operation or a write operation.

In some examples, the writing component 555 may be configured as or otherwise support a means for performing, during the fourth duration, a write operation on a fifth block of non-volatile memory cells of the memory system concurrent with refreshing the fourth block of non-volatile memory cells, where a cadence associated with performing the write operation and refreshing the fourth block of non-volatile memory cells is adjustable based at least in part on one or more performance criteria of the memory system.

In some examples, the second duration is associated with an idle duration of the memory system.

In some examples, the first block includes a production state awareness (PSA) block and the second block includes a non-PSA block.

FIG. 6 illustrates a flowchart showing a method 600 that supports prioritizing refresh operations of a memory system in accordance with examples as disclosed herein. The operations of method 600 may be implemented by a memory system or its components as described herein. For example, the operations of method 600 may be performed by a memory system as described with reference to FIGS. 1 through 5. In some examples, a memory system may execute a set of instructions to control the functional elements of the device to perform the described functions. Additionally, or alternatively, the memory system may perform aspects of the described functions using special-purpose hardware.

At 605, the method may include transitioning, by a memory system, from a first power state to a second power state after a reflow operation. The operations of 605 may be performed in accordance with examples as disclosed herein. In some examples, aspects of the operations of 605 may be performed by a power state component 525 as described with reference to FIG. 5.

At 610, the method may include refreshing, for a first duration, a first block of non-volatile memory cells of the memory system based at least in part on transitioning from the first power state to the second power state, where the first block has a first bit error rate that is within a first range of bit error rates. The operations of 610 may be performed in accordance with examples as disclosed herein. In some examples, aspects of the operations of 610 may be performed by a refreshing component 530 as described with reference to FIG. 5.

At 615, the method may include determining whether a second block of non-volatile memory cells of the memory system has a second bit error rate that is within a second range of bit error rates based at least in part on refreshing the first block. The operations of 615 may be performed in accordance with examples as disclosed herein. In some examples, aspects of the operations of 615 may be performed by a determination component 535 as described with reference to FIG. 5.

At 620, the method may include refreshing, during a second duration that corresponds to the second range of bit error rates, the second block of non-volatile memory cells based at least in part on determining that the second bit error rate is within the second range of bit error rates. The operations of 620 may be performed in accordance with examples as disclosed herein. In some examples, aspects of the operations of 620 may be performed by a refreshing component 530 as described with reference to FIG. 5.

In some examples, an apparatus as described herein may perform a method or methods, such as the method 600. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for transitioning, by a memory system, from a first power state to a second power state after a reflow operation; refreshing, for a first duration, a first block of non-volatile memory cells of the memory system based at least in part on transitioning from the first power state to the second power state, where the first block has a first bit error rate that is within a first range of bit error rates; determining whether a second block of non-volatile memory cells of the memory system has a second bit error rate that is within a second range of bit error rates based at least in part on refreshing the first block; and refreshing, during a second duration that corresponds to the second range of bit error rates, the second block of non-volatile memory cells based at least in part on determining that the second bit error rate is within the second range of bit error rates.

Aspect 2: The method, apparatus, or non-transitory computer-readable medium of aspect 1, further including operations, features, circuitry, logic, means, or instructions, or any combination thereof for associating the first block of non-volatile memory cells with the first range of bit error rates based at least in part on transitioning from the first power state to the second power state, where refreshing the first block of non-volatile memory cells for the first duration is based at least in part on associating the first block of non-volatile memory cells with the first range of bit error rates.

Aspect 3: The method, apparatus, or non-transitory computer-readable medium of aspect 2, further including operations, features, circuitry, logic, means, or instructions, or any combination thereof for determining that a third block of non-volatile memory cells of the memory system has a third bit error rate that is within a third range of bit error rates and refraining from refreshing, for the first duration, the third block of non-volatile memory cells based at least in part on determining that the third bit error rate of the third block is within the third range of bit error rates.

Aspect 4: The method, apparatus, or non-transitory computer-readable medium of any of aspects 1 through 3, further including operations, features, circuitry, logic, means, or instructions, or any combination thereof for receiving a write command associated with the second block of non-volatile memory cells and assigning a timestamp to the second block of non-volatile memory cells based at least in part on receiving the write command, where determining whether the second block of non-volatile memory cells has the second bit error rate is based at least in part on assigning the timestamp.

Aspect 5: The method, apparatus, or non-transitory computer-readable medium of aspect 4, further including operations, features, circuitry, logic, means, or instructions, or any combination thereof for transitioning, by the memory system for a second time, from the first power state to the second power state; determining that the second block of non-volatile memory cells has the second bit error rate based at least in part on the timestamp and transitioning from the first power state to the second power state; and determining that the second bit error rate satisfies a threshold value based at least in part on determining that the second block of non-volatile memory cells has the second bit error rate.

Aspect 6: The method, apparatus, or non-transitory computer-readable medium of aspect 5, further including operations, features, circuitry, logic, means, or instructions, or any combination thereof for associating the second block of non-volatile memory cells with the second range of bit error rates based at least in part on determining that the second bit error rate satisfies the threshold value, where the second block of non-volatile memory cells is refreshed during the second duration based at least in part on associating the second block of non-volatile memory cells with the second range of bit error rates.

Aspect 7: The method, apparatus, or non-transitory computer-readable medium of aspect 6, further including operations, features, circuitry, logic, means, or instructions, or any combination thereof for receiving a command from a host system based at least in part on determining that the second bit error rate satisfies the threshold value, where the command indicates a third duration for associating the second block of non-volatile memory cells with the second range of bit error rates, where the third duration occurs after the first duration and before the second duration.

Aspect 8: The method, apparatus, or non-transitory computer-readable medium of any of aspects 6 through 7, where associating the second block of non-volatile memory cells with the second range of bit error rates occurs absent receiving a command from a host system.

Aspect 9: The method, apparatus, or non-transitory computer-readable medium of any of aspects 1 through 8, further including operations, features, circuitry, logic, means, or instructions, or any combination thereof for determining that a fourth block of non-volatile memory cells of the memory system has a fourth bit error rate that is within a fourth range of bit error rates based at least in part on determining whether the second block of non-volatile memory cells of the memory system has the second bit error rate and refreshing, during a fourth duration that corresponds to the fourth range of bit error rates, the fourth block of non-volatile memory cells based at least in part on determining that the fourth bit error rate is within the fourth range of bit error rates.

Aspect 10: The method, apparatus, or non-transitory computer-readable medium of aspect 9, where the fourth duration is associated with a duration when the memory system is performing a read operation or a write operation.

Aspect 11: The method, apparatus, or non-transitory computer-readable medium of any of aspects 9 through 10, further including operations, features, circuitry, logic, means, or instructions, or any combination thereof for performing, during the fourth duration, a write operation on a fifth block of non-volatile memory cells of the memory system concurrent with refreshing the fourth block of non-volatile memory cells, where a cadence associated with performing the write operation and refreshing the fourth block of non-volatile memory cells is adjustable based at least in part on one or more performance criteria of the memory system.

Aspect 12: The method, apparatus, or non-transitory computer-readable medium of any of aspects 1 through 11, where the second duration is associated with an idle duration of the memory system.

Aspect 13: The method, apparatus, or non-transitory computer-readable medium of any of aspects 1 through 12, where the first block includes a production state awareness (PSA) block and the second block includes a non-PSA block.

It should be noted that the described techniques include possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, symbols, and chips that may be referenced throughout the description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” refers to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow:

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

Additionally, the terms “directly in response to” or “in direct response to” may refer to one condition or action occurring as a direct result of a previous condition or action. In some examples, a first condition or action may be performed and second condition or action may occur directly as a result of the previous condition or action occurring independent of whether other conditions or actions occur. In some examples, a first condition or action may be performed and second condition or action may occur directly as a result of the previous condition or action occurring, such that no other intermediate conditions or actions occur between the earlier condition or action and the second condition or action or a limited quantity of one or more intermediate steps or actions occur between the earlier condition or action and the second condition or action. Any condition or action described herein as being performed “based on,” “based at least in part on,” or “in response to” some other step, action, event, or condition may additionally, or alternatively (e.g., in an alternative example), be performed “in direct response to” or “directly in response to” such other condition or action unless otherwise specified.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processor, firmware, or any combination thereof. If implemented in software executed by a processor, the functions may be stored on or transmitted over, as one or more instructions or code, a computer-readable medium. Other examples and implementations are within the scope of the disclosure and appended claims. For example, due to the nature of software, the described functions can be implemented using software executed by a processor, hardware, firmware, hardwiring, or combinations of any of these. Features implementing functions may also be physically located at various positions, including being distributed such that portions of functions are implemented at different physical locations.

For example, the various illustrative blocks and components described in connection with the disclosure herein may be implemented or performed with a general-purpose processor, a DSP, an ASIC, an FPGA or other programmable logic device, discrete gate or transistor logic, discrete hardware components, or any combination thereof designed to perform the functions described herein. A general-purpose processor may be a microprocessor, but in the alternative, the processor may be any processor, controller, microcontroller, or state machine. A processor may be implemented as a combination of computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

Computer-readable media includes both non-transitory computer storage media and communication media including any medium that facilitates transfer of a computer program from one place to another. A non-transitory storage medium may be any available medium that can be accessed by a general purpose or special purpose computer. By way of example, and not limitation, non-transitory computer-readable media can comprise RAM, ROM, electrically erasable programmable read-only memory (EEPROM), compact disk (CD) ROM or other optical disk storage, magnetic disk storage or other magnetic storage devices, or any other non-transitory medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, include CD, laser disc, optical disc, digital versatile disc (DVD), floppy disk, and Blu-ray disc, where disks usually reproduce data magnetically, while discs reproduce data optically with lasers. Combinations of these are also included within the scope of computer-readable media.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. An apparatus, comprising:
a controller associated with a memory device, wherein the controller is configured to cause the apparatus to:
transition from a first power state to a second power state after a reflow operation;
refreshing, for a first duration, a first block of non-volatile memory cells of the memory device based at least in part on transitioning from the first power state to the second power state, wherein the first block has a first bit error rate that is within a first range of bit error rates;
determine whether a second block of non-volatile memory cells of the memory device has a second bit error rate that is within a second range of bit error rates based at least in part on refreshing the first block; and
refresh, during a second duration that corresponds to the second range of bit error rates, the second block of non-volatile memory cells based at least in part on determining that the second bit error rate is within the second range of bit error rates.

2. The apparatus of claim 1, wherein the controller is further configured to cause the apparatus to:
associate the first block of non-volatile memory cells with the first range of bit error rates based at least in part on transitioning from the first power state to the second power state, wherein refreshing the first block of non-volatile memory cells for the first duration is based at least in part on associating the first block of non-volatile memory cells with the first range of bit error rates.

3. The apparatus of claim 2, wherein the controller is further configured to cause the apparatus to:
determine that a third block of non-volatile memory cells of the memory device has a third bit error rate that is within a third range of bit error rates; and
refrain from refreshing, for the first duration, the third block of non-volatile memory cells based at least in part on determining that the third bit error rate of the third block is within the third range of bit error rates.

4. The apparatus of claim 1, wherein the controller is further configured to cause the apparatus to:
receive a write command associated with the second block of non-volatile memory cells; and
assign a timestamp to the second block of non-volatile memory cells based at least in part on receiving the write command, wherein determining whether the second block of non-volatile memory cells has the second bit error rate is based at least in part on assigning the timestamp.

5. The apparatus of claim 4, wherein the controller is further configured to cause the apparatus to:
transition from the first power state to the second power state:
determine that the second block of non-volatile memory cells has the second bit error rate based at least in part on the timestamp and transitioning from the first power state to the second power state; and
determine that the second bit error rate satisfies a threshold value based at least in part on determining that the second block of non-volatile memory cells has the second bit error rate.

6. The apparatus of claim 5, wherein the controller is further configured to cause the apparatus to:
associate the second block of non-volatile memory cells with the second range of bit error rates based at least in part on determining that the second bit error rate satisfies the threshold value, wherein the second block of non-volatile memory cells is refreshed during the second duration based at least in part on associating the second block of non-volatile memory cells with the second range of bit error rates.

7. The apparatus of claim 6, wherein the controller is further configured to cause the apparatus to:
receive a command from a host system based at least in part on determining that the second bit error rate satisfies the threshold value, wherein the command indicates a third duration for associating the second block of non-volatile memory cells with the second range of bit error rates, wherein the third duration occurs after the first duration and before the second duration.

8. The apparatus of claim 6, wherein associating the second block of non-volatile memory cells with the second range of bit error rates occurs absent receiving a command from a host system.

9. The apparatus of claim 1, wherein the controller is further configured to cause the apparatus to:
determine that a fourth block of non-volatile memory cells of the memory device has a fourth bit error rate that is within a fourth range of bit error rates based at least in part on determining whether the second block of non-volatile memory cells of the memory device has the second bit error rate; and
refresh, during a fourth duration that corresponds to the fourth range of bit error rates, the fourth block of non-volatile memory cells based at least in part on determining that the fourth bit error rate is within the fourth range of bit error rates.

10. The apparatus of claim 9, wherein the fourth duration is associated with a duration when the memory device is performing a read operation or a write operation.

11. The apparatus of claim 9, wherein the controller is further configured to cause the apparatus to:
perform, during the fourth duration, a write operation on a fifth block of non-volatile memory cells of the memory device concurrent with refreshing the fourth block of non-volatile memory cells, wherein a cadence associated with performing the write operation and refreshing the fourth block of non-volatile memory cells is adjustable based at least in part on one or more performance criteria of the memory device.

12. The apparatus of claim 1, wherein the second duration is associated with an idle duration of the memory device.

13. The apparatus of claim 1, wherein the first block comprises a production state awareness (PSA) block and the second block comprises a non-PSA block.

14. A non-transitory computer-readable medium storing code comprising instructions which, when executed by a processor of an electronic device, cause the electronic device to:
transition, by a memory system, from a first power state to a second power state after a reflow operation;
refreshing, for a first duration, a first block of non-volatile memory cells of the memory system based at least in part on transitioning from the first power state to the second power state, wherein the first block has a first bit error rate that is within a first range of bit error rates;
determine whether a second block of non-volatile memory cells of the memory system has a second bit error rate that is within a second range of bit error rates based at least in part on refreshing the first block; and
refresh, during a second duration that corresponds to the second range of bit error rates, the second block of non-volatile memory cells based at least in part on determining that the second bit error rate is within the second range of bit error rates.

15. The non-transitory computer-readable medium of claim 14, wherein the instructions, when executed by the processor of the electronic device, further cause the electronic device to:
associate the first block of non-volatile memory cells with the first range of bit error rates based at least in part on transitioning from the first power state to the second power state, wherein refreshing the first block of non-volatile memory cells for the first duration is based at least in part on associating the first block of non-volatile memory cells with the first range of bit error rates.

16. The non-transitory computer-readable medium of claim 15, wherein the instructions, when executed by the processor of the electronic device, further cause the electronic device to:
determine that a third block of non-volatile memory cells of the memory system has a third bit error rate that is within a third range of bit error rates; and
refrain from refreshing, for the first duration, the third block of non-volatile memory cells based at least in part on determining that the third bit error rate of the third block is within the third range of bit error rates.

17. The non-transitory computer-readable medium of claim 14, wherein the instructions, when executed by the processor of the electronic device, further cause the electronic device to:
receive a write command associated with the second block of non-volatile memory cells; and
assign a timestamp to the second block of non-volatile memory cells based at least in part on receiving the write command, wherein determining whether the second block of non-volatile memory cells has the second bit error rate is based at least in part on assigning the timestamp.

18. The non-transitory computer-readable medium of claim 17, wherein the instructions, when executed by the processor of the electronic device, further cause the electronic device to:
transition, by the memory system for a second time, from the first power state to the second power state;
determine that the second block of non-volatile memory cells has the second bit error rate based at least in part on the timestamp and transitioning from the first power state to the second power state; and
determine that the second bit error rate satisfies a threshold value based at least in part on determining that the second block of non-volatile memory cells has the second bit error rate.

19. The non-transitory computer-readable medium of claim 18, wherein the instructions, when executed by the processor of the electronic device, further cause the electronic device to:
associate the second block of non-volatile memory cells with the second range of bit error rates based at least in part on determining that the second bit error rate satisfies the threshold value, wherein the second block of non-volatile memory cells is refreshed during the second duration based at least in part on associating the second block of non-volatile memory cells with the second range of bit error rates.

20. A method, comprising:
transitioning, by a memory system, from a first power state to a second power state after a reflow operation;
refreshing, for a first duration, a first block of non-volatile memory cells of the memory system based at least in part on transitioning from the first power state to the second power state, wherein the first block has a first bit error rate that is within a first range of bit error rates;
determining whether a second block of non-volatile memory cells of the memory system has a second bit error rate that is within a second range of bit error rates based at least in part on refreshing the first block; and
refreshing, during a second duration that corresponds to the second range of bit error rates, the second block of non-volatile memory cells based at least in part on determining that the second bit error rate is within the second range of bit error rates.
